(19) United States
(12) Patent Application Publication
(10) Pub. No.: US 2015/0048463 A1
(43) Pub. Date: Feb. 19, 2015

(54) PACKAGE DEVICE FOR MICROELECTROMECHANICAL INERTIAL SENSOR

(71) Applicant: TXC CORPORATION, TAIPEI (TW)

(72) Inventor: CHIEN-WEI CHIANG, TAO YUAN COUNTY (TW)

(73) Assignee: TXC CORPORATION, TAIPEI (TW)

(21) Appl. No.: 13/968,830

(22) Filed: Aug. 16, 2013

(51) Int. Cl. B81B 7/00

(52) U.S. Cl. CPC B81B 7/007; B81B 2201/0228
USPC 257/417

(57) ABSTRACT

A package device for a microelectromechanical inertial sensor comprises a ceramic substrate having an upper accommodation space and a lower accommodation and having a plurality of interconnect metal lines thereinside; a microelectromechanical system (MEMS) chip mounted inside the upper accommodation of the ceramic substrate and electrically connected with the interconnect metal lines; a top cover arranged on the ceramic substrate and sealing the upper accommodation space; and an integrated circuit (IC) chip mounted inside the lower accommodation space and electrically connected with the interconnect metal lines. The present invention can improve the reliability of components, increase the yield and decrease the fabrication cost.

### BACKGROUND OF THE INVENTION

1. Field of the Invention

The present invention relates to a package structure for a sensor, particularly to a package device for a microelectromechanical inertial sensor.

2. Description of the Related Art

In semiconductor industry, the micromaching technology is used to fabricate various micro sensors and micro actuators. Further, the micro sensor or micro actuator may be integrated with a micro electronic circuit to form MEMS (microelectromechanical system). The fabrication of MEMS components involves many fields of technologies. However, most MEMS components, such as inertial sensors, contain a floating structure fabricated by the micromachining technology and only having few support points to increase sensitivity.

Refer to FIG. 1 for a conventional package structure of a microelectromechanical inertial sensor. In the conventional package structure of a microelectromechanical inertial sensor, an IC (Integrated Circuit) chip 12 is arranged on a substrate 10. The IC chip 12 is electrically connected with the wiring of the substrate 10 by a plurality of bonding wires 14. A microelectromechanical chip 16 having a microelectromechanical component 18 is arranged on the IC chip 12 and electrically connected with the IC chip 12 by a plurality of bonding wires 20. A silicon top cover 22 covers the microelectromechanical chip 16 and hermetic seals the microelectromechanical component 18. Then, a sealing resin 24 wraps the IC chip 12, the microelectromechanical chip 16, the silicon top cover 22, and the bonding wires 14 and 20. Thereby is completed the package structure of the microelectromechanical inertial sensor.

Refer to FIG. 2 for another conventional package structure of a microelectromechanical inertial sensor. In the package structure of the microelectromechanical inertial sensor, an IC (Integrated Circuit) chip 54 is arranged on a substrate 50 and mounted in a groove 52 of the substrate 50. The IC chip 54 is electrically connected with the wiring of the substrate 50 by a plurality of flip-chip bumps 56. A microelectromechanical chip 58 having a microelectromechanical component 60 is arranged on the IC chip 54 and electrically connected with the IC chip 54 by a plurality of bonding wires 62. A silicon cover 61 hermetic seals the microelectromechanical component 60 and a top cover covers the microelectromechanical chip 58 and covers the microelectromechanical chip 58, the IC chip 54, bumps 56, and the bonding wires 62. Thereby is completed the package structure of the microelectromechanical inertial sensor.

Refer to FIG. 3 for further another conventional package structure of a microelectromechanical inertial sensor. In the package structure of the microelectromechanical inertial sensor, a microelectromechanical and IC (Integrated Circuit) chip 64 having a microelectromechanical component 65 is arranged on a substrate 66 and mounted in a groove 68 of the substrate 66. The chip 64 is electrically connected with the wiring of the substrate 66 by a plurality of bonding wires 70. A top cover 72 covers the chip 64 and hermetic seals the chip 64, and the bonding wires 62. Thereby is completed the package structure of the microelectromechanical inertial sensor.

However, the abovementioned conventional complicated package structure of a microelectromechanical inertial sensor has a higher package cost. The electric connection thereof is realized by a wire-bonding technology. Although the microelectromechanical chip is verified to operate normally after wire-bonding, the succeeding resin molding process may damage the bonding wires and lower the yield thereof Furthermore, in order to reduce the cost of packaging and design special integrated process, its expensive manufacturing process caused the higher fabrication cost.

Accordingly, the present invention proposes a novel package device for a microelectromechanical inertial sensor to overcome the problems (such as the high defective rate) of the conventional microelectromechanical package technology without increasing the fabrication cost.

### SUMMARY OF THE INVENTION

The primary objective of the present invention is to provide a package device for a microelectromechanical inertial sensor to raise the reliability and yield of the products and lower the fabrication cost thereof.

Another objective of the present invention is to provide a package device for a microelectromechanical inertial sensor, wherein the IC chip is mounted after the test of the MEMS chip so as to decrease the defective rate of the products.

To achieve the abovementioned objectives, the present invention proposes a package device for a microelectromechanical inertial sensor, which comprises a ceramic substrate, an MEMS chip, a top cover, and an IC chip. The ceramic substrate is a high-temperature or low-temperature co-fired multilayer ceramic substrate. The ceramic substrate has an upper accommodation space and a lower accommodation space. The ceramic substrate also has a plurality of interconnect metal lines thereinside. The MEMS chip has microelectromechanical components and is mounted in the upper accommodation space and electrically connected with the ceramic substrate. The IC chip is mounted in the lower accommodation space and electrically connected with the ceramic substrate . The MEMS chip is electrically connected with the IC chip by the interconnect metal lines of the ceramic substrate. The top cover and a metallic ring are arranged on the ceramic substrate to seal the MEMS components and keep the upper accommodation space in an hermetic state or a vacuum state. Compared with the resin-based package, the ceramic substrate-based package has lower residual stress and higher yield.

In one embodiment, the ceramic substrate is an H-shaped substrate; the MEMS chip is mounted in the upper accommodation space thereof, and the IC chip is mounted in the lower accommodation space thereof.

Below, embodiments are described in detail in cooperation with the attached drawings to make easily understood the objectives, technical contents, characteristics and accomplishments of the present invention.

### BRIEF DESCRIPTION OF THE DRAWINGS

FIG. 1 schematically shows a conventional package structure of a microelectromechanical inertial sensor;

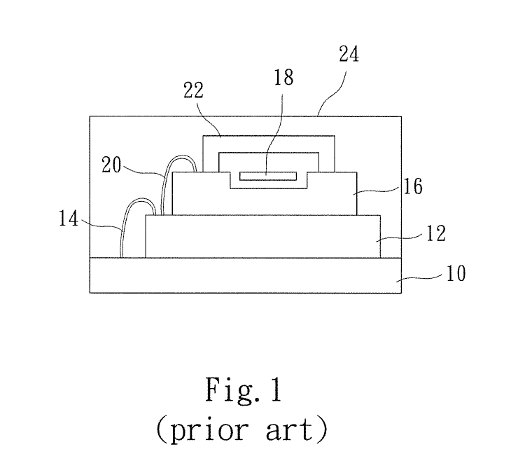

FIG. 2 schematically shows another conventional package structure of a microelectromechanical inertial sensor;

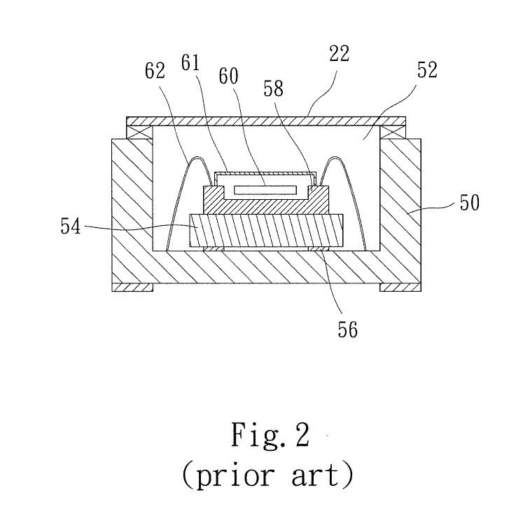

FIG. 3 schematically shows a further another conventional package structure of a microelectromechanical inertial sensor;

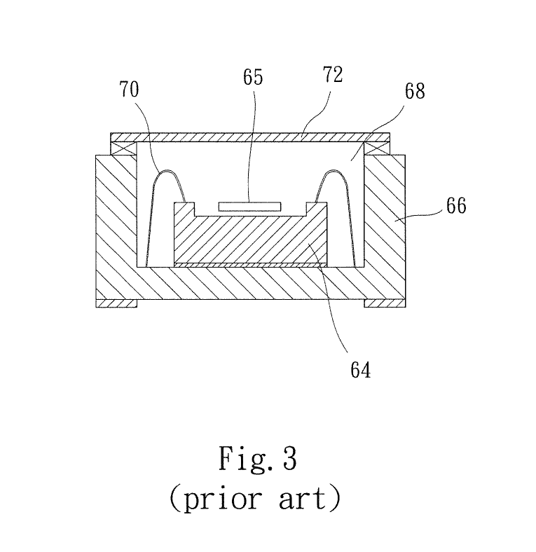

FIG. 4 schematically shows a package device for a microelectromechanical inertial sensor according to one embodiment of the present invention;

FIG. 5 shows a perspective exploded view of the package device shown in FIG. 4.

FIG. 6 schematically shows electric-conduction pads arranged on the bottom surface of the ceramic substrate according to one embodiment of the present invention; and

FIG. 7 schematically shows a package device for a microelectromechanical inertial sensor according to another embodiment of the present invention.

### DETAILED DESCRIPTION OF THE INVENTION

The present invention is characterized in that the ceramic substrate has two accommodation spaces where an MEMS chip and an IC chip are respectively mounted, and that the MEMS chip and the IC chip are mounted in a flip-chip technology, and that a metal top cover is used to seal the MEMS chip. Thereby, the present invention can raise the reliability and yield of the products.

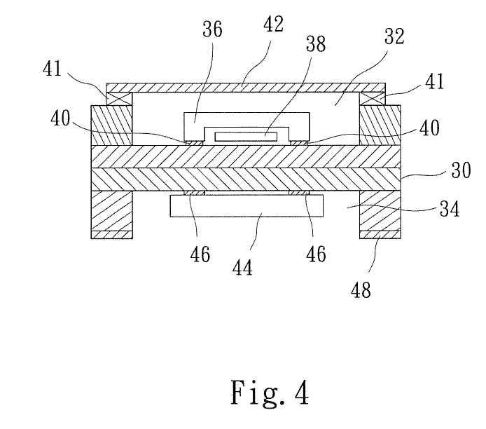

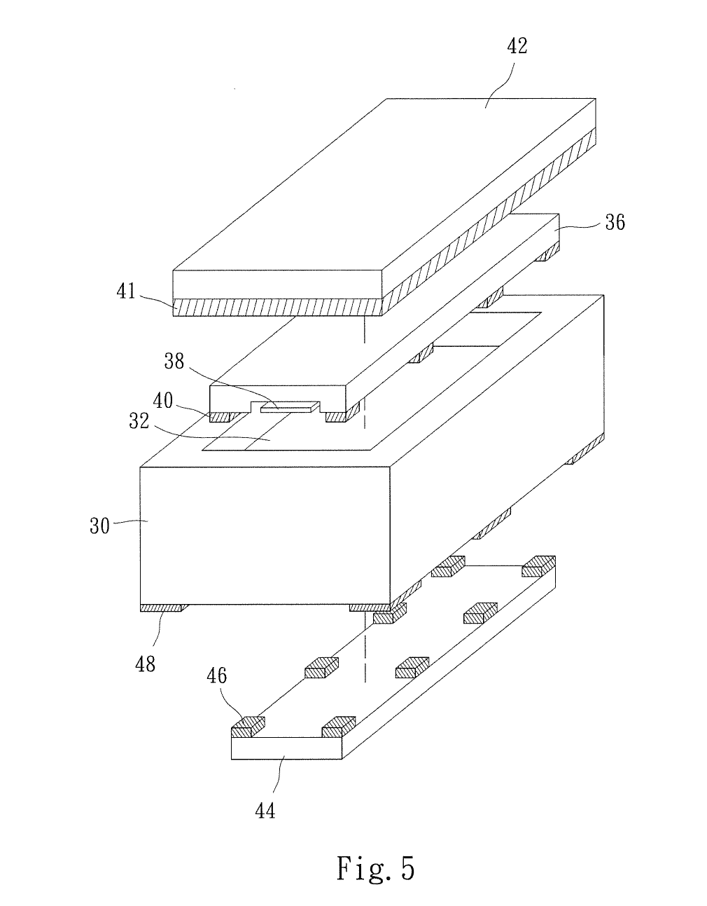

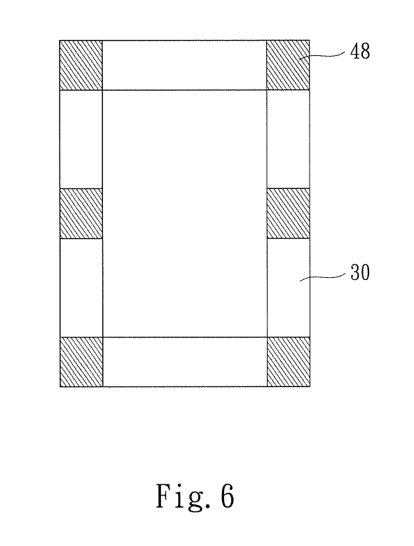

Refer to FIG. 4 and FIG. 5. FIG. 4 schematically shows a package device for a microelectromechanical inertial sensor according to one embodiment of the present invention. FIG. 5 shows a perspective exploded view of the package device shown in FIG. 4. In the embodiment shown in FIG. 4 and FIG. 5, the package device for a microelectromechanical inertial sensor comprises a ceramic substrate, an MEMS chip 36, a top cover 42, and an IC chip 44. The ceramic substrate is a high-temperature or low-temperature co-fired multilayer ceramic substrate. In this embodiment, the ceramic substrate is exemplified by an H-shaped substrate 30. The H-shaped substrate 30 has an upper accommodation space 32 and a lower accommodation space 34, which are respectively formed on the upper side and lower side of the H-shaped substrate 30. In this embodiment, the H-shaped substrate 30 is formed via stacking several layers of substrates having a plurality of interconnect metal lines (not shown in the drawings) thereinside. At least one microelectromechanical component 38 has been fabricated in the MEMS chip 36 beforehand. The MEMS chip 36 is arranged inside the upper accommodation space 32 downward from the top of the H-shaped substrate 30 in a flip-chip method and electrically connected with the interconnect metal lines by a plurality of first electric-conduction bumps 40. A metallic ring 41 and the top cover 42 (preferably made of a metallic material) are arranged on the top of the H-shaped substrate 30 to seal the MEMS chip 36 and keep the upper accommodation space 32 in a highly hermetic state or a vacuum state, whereby the microelectromechanical component 38 is able to operate normally and exempted from interference. The IC chip 44 is arranged inside the lower accommodation space 34 upward from the bottom of the H-shaped substrate 30 in a flip-chip method and electrically connected with the interconnect metal lines by a plurality of second electric-conduction bumps 46. A plurality of electric-conduction pads 48 is arranged on the perimeter of the bottom surface of the H-shaped substrate 30. In the present invention, the H-shaped substrate 30 may be designed to have different quantities and different distribution patterns of the electric-conduction pads 48 according to different requirements. For example, there are six electric-conduction pads 48 in the embodiment shown in FIG. 6. However, the present invention is not limited by the embodiment shown in FIG. 6. The electric-conduction pads 48 are electrically connected with the interconnect metal lines, functioning as contact points to the external printed circuit board for signal communication.

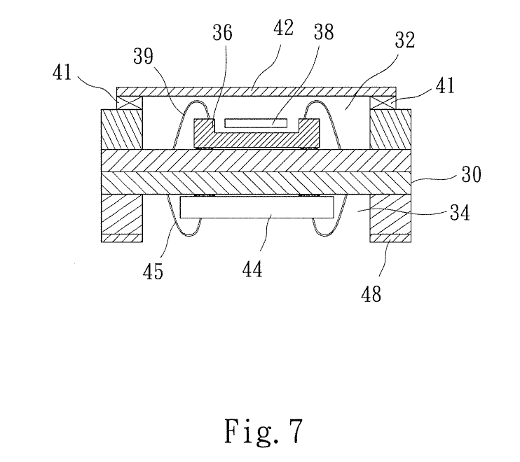

In addition to the abovementioned embodiment, electrically connection structures have other forms in other embodiments. Refer to FIG. 7. FIG. 7 schematically shows a package device for a microelectromechanical inertial sensor according to another embodiment of the present invention.

In the embodiment shown in FIG. 7, the package device for a microelectromechanical inertial sensor comprises a H-shaped ceramic substrate 30, an MEMS chip 36, a top cover 42, and an IC chip 44. Similarly, the H-shaped ceramic substrate 30 has an upper accommodation space 32 and a lower accommodation space 34, which are respectively formed on the upper side and lower side of the H-shaped ceramic substrate 30. In this embodiment, the H-shaped ceramic substrate 30 is formed via stacking several layers of substrates having a plurality of interconnect metal lines (not shown in the drawings) thereinside. At least one microelectromechanical component 38 has been fabricated in the MEMS chip 36 beforehand. The MEMS chip 36 is arranged inside the upper accommodation space 32 downward from the top of the H-shaped substrate 30 and electrically connected with the interconnect metal lines by a plurality of first bonding wires 39. A metallic ring 41 and the top cover 42 are arranged on the top of the H-shaped ceramic substrate 30 to seal the MEMS chip 36 and keep the upper accommodation space 32 in a highly hermetic state or a vacuum state. The IC chip 44 is arranged inside the lower accommodation space 34 upward from the bottom of the H-shaped substrate 30 and electrically connected with the interconnect metal lines by a plurality of second bonding wires 45. A plurality of electric-conduction pads 48 is arranged on the perimeter of the bottom surface of the H-shaped ceramic substrate 30. In the present invention, the MEMS chip will be tested and classified after the hermetic or vacuum environment has been established inside the upper accommodation space. The package process will not be continued unless the MEMS chip in the ceramic substrate has been qualified. Therefore, the present invention can decrease the defective rate, raise the yield, and reduce the fabrication cost.

The embodiments described above are to demonstrate the technical thought and characteristics of the present invention to enable the persons skilled in the art to understand, make, and use the present invention. However, these embodiments are not intended to limit the scope of the present invention. Any equivalent modification or variation according to the spirit of the present invention is to be also included within the scope of the present invention.

What is claimed is:

1. A package device for a microelectromechanical inertial sensor, comprising
a ceramic substrate having an upper accommodation space and a lower accommodation and having a plurality of interconnect metal lines thereinside;
a microelectromechanical system (MEMS) chip having at least one microelectromechanical component, mounted inside said upper accommodation of said ceramic substrate and electrically connected with said interconnect metal lines;
a top cover arranged on said ceramic substrate and sealing said upper accommodation space; and
an integrated circuit (IC) chip mounted inside said lower accommodation space and electrically connected with said interconnect metal lines.

2. The package device for a microelectromechanical inertial sensor according to claim 1, wherein said ceramic substrate is an H-shaped substrate, and wherein said MEMS chip is mounted in said upper accommodation space in a flip-chip method, and wherein said IC chip is mounted in said lower accommodation space in a flip-chip method.

3. The package device for a microelectromechanical inertial sensor according to claim 2, wherein said ceramic substrate is formed via stacking a plurality of layers of substrates.

4. The package device for a microelectromechanical inertial sensor according to claim 2, wherein said microelectromechanical system (MEMS) chip electrically connected with said interconnect metal lines by a plurality of first electric-conduction bumps or first bonding wires.

5. The package device for a microelectromechanical inertial sensor according to claim 4, wherein said integrated circuit (IC) chip mounted inside said lower accommodation space and electrically connected with said interconnect metal lines by a plurality of second electric-conduction bumps or second bonding wires.

6. The package device for a microelectromechanical inertial sensor according to claim 1, wherein said top cover is a metallic top cover.

7. The package device for a microelectromechanical inertial sensor according to claim 1, wherein said upper accommodation space is hermetic sealed to have a vacuum state.

8. The package device for a microelectromechanical inertial sensor according to claim 1 further comprising a plurality of electric-conduction pads arranged on a bottom surface of said ceramic substrate and electrically connected with said interconnect metal lines to function as contact points for external communication.

9. The package device for a microelectromechanical inertial sensor according to claim 1, wherein said ceramic substrate is made of a high-temperature co-fired multilayer ceramic or a low-temperature co-fired multilayer ceramic.

10. The package device for a microelectromechanical inertial sensor according to claim 6, wherein a metallic ring is arranged between said ceramic substrate and said top cover.
